(19) United States
(12) Patent Application Publication
(10) Pub. No.: US 2007/0221613 A1
(43) Pub. Date: Sep. 27, 2007

(54) Structure for stopping mechanical cracks in a substrate wafer, use of the structure and a method for producing the structure

(76) Inventors: Martin Ulrich Gutsche, Dorfen (DE); Harald Seidl, Poering (DE); Ronald J. Schutz, Dresden (DE)

Correspondence Address: SLATER & MATSIL LLP, 17950 PRESTON ROAD, SUITE 1000, DALLAS, TX, 75252, US

(21) Appl. No.: 11/388,255

(22) Filed: Mar. 23, 2006

(51) Int. Cl. C03C 15/00; H01L 47/00

(52) U.S. Cl. 216/57; 216/58; 216/83; 257/1

(57) ABSTRACT

A structure for stopping mechanical cracks in a substrate wafer used for semiconductor device manufacturing, especially a silicon wafer, is described. The structure includes at least one depression that extends into the substrate wafer for at least 20% of the final thickness of the substrate wafer.

### TECHNICAL FIELD

This invention relates generally to the manufacture of semiconductor devices, especially a substrate wafer with at least one crack stop structure to be used in the manufacturing of semiconductor devices. The invention also relates to the use of a crack stop structure and a method for manufacturing a crack stop structure.

### BACKGROUND

In the manufacturing of semiconductor devices, a substrate wafer forms the basis from which individual devices, such as DRAM chips or microprocessors, are manufactured. It is known that a substrate wafer made from, e.g., silicon, germanium, InP or GaAs wafers, is used for such purposes.

To improve the yield of the processes, substrate wafers become larger, making the mechanical handling more difficult. With increasing diameters, substrate wafers are more prone to mechanical stress within the substrate wafer, which occurs during the substrate wafer handling. Since the substrate wafers are subjected to an increasing number of process steps, this problem becomes pronounced.

Especially problematic is the process step in which the devices, such as chips, are cut from the substrate wafer. Pieces of the substrate wafer can break off from the edges or corners of the dies. That is, pieces tend to break off the edge of the chips or dies directly next to the kerf. The kerf is the slot left in the substrate wafer by the saw used to dice the substrate wafer into chips or dies.

So far, crack stop lines have been used to reduce the occurrence of chipping along the edges and the corners of dies. Those crack stop lines may consist of stacked metal lines that are connected (stitched) by via holes filled with conducting material (e.g., tungsten). The crack stop lines minimize the delamination of films that have been deposited on the surface of the die. However, they cannot prevent cleave lines in the substrate wafer, originating at the edge of the die, from running into the active substrate wafer region of the chip, thus causing the chip to malfunction.

That is, all of the crack stop designs that are currently used, utilize structures within the thin films that are added to the surface of a substrate wafers during the fabrication of the chips or dies.

### SUMMARY OF THE INVENTION

Embodiments of invention are concerned with forming crack stop structures that penetrate into the substrate wafer itself. These structures are much more effective in trapping cracks that could form in the kerf and penetrate into the chip region. Furthermore, embodiments of the invention utilize etching processes for these structures that are already necessarily used to fabricate the chips or dies.

Two examples of processes that could be used to form these new crack stops are deep trench etches used to form capacitor structures in, for example DRAM circuits, and through silicon contact etches used to transfer contact regions from the top of the substrate wafer surface on which devices are made, to the back of the chip. Such through contacts then enable die stacking technologies.

The preferred embodiment structure for stopping mechanical cracks comprises at least a depression extending into the substrate wafer for at least 20%, especially 5% of the final thickness of the substrate wafer. This is especially applicable to silicon wafers as substrates.

By positioning the depressions relatively deep into the substrate wafer, especially relative to the other parts of the electronic devices on the substrate wafer, it is assured that cracks are intercepted by the depressions so that they cannot propagate over a larger area, thereby harming the functionality of the devices.

### BRIEF DESCRIPTION OF THE DRAWINGS

Other advantages of the invention become apparent upon reading of the detailed description of the invention and the appended claims provided below, and upon reference to the drawings.

FIG. 1 shows schematically a top view of a substrate wafer, that is, a wafer on which a series of devices or chips have been fabricated each of which is surrounded by a crack stop structure;

FIG. 1A shows a cross-section view along the line A-A in FIG. 1;

FIG. 1B shows a cross-section view along the line A-A in FIG. 1 with an alternative embodiment a trench filled with material;

FIG. 2 shows schematically a top view of a rectangular chip or device with a rectangular continuous crack stop structure;

FIG. 2A shows a cross-section view along the line B-B in FIG. 2;

FIG. 3 shows schematically a top view of a rectangular chip or device with a rectangular, point wise crack stop structure;

FIG. 4 shows a top view of a rectangular chip or device with trenches and holes as a crack stop structure;

FIG. 5 shows a top view of a rectangular chip or device with trenches or holes in a zig-zag arrangement as a crack stop structure;

FIG. 5A shows a cross-section of the crack stop structure in FIG. 5;

FIG. 6A shows a top view of a device cut from a substrate wafer without a crack stop structure;

FIG. 6B shows a top view of a device cut from a substrate wafer with a crack stop structure; and

FIGS. 7A and 7B show a side view of a substrate wafer before and after backgrinding.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

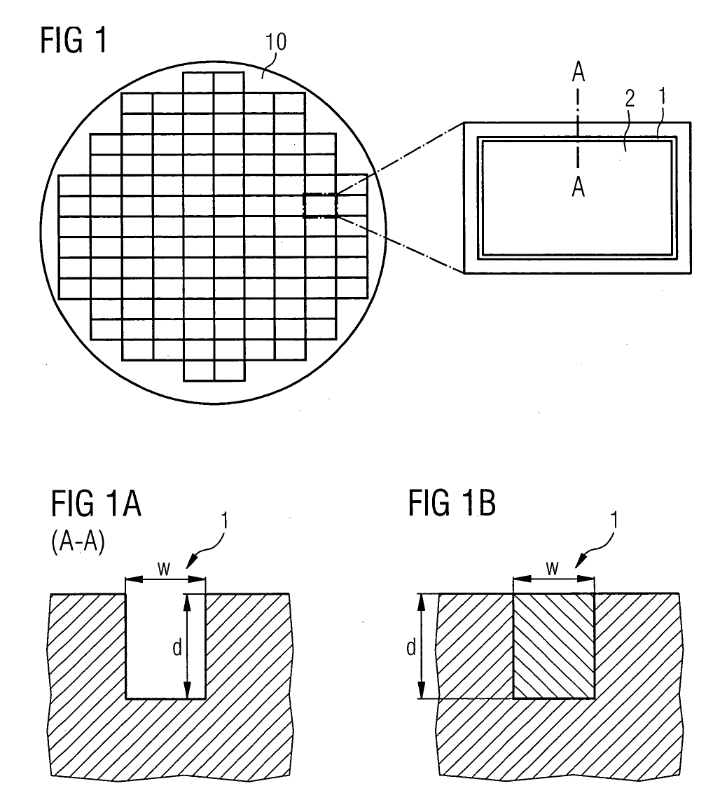

FIG. 1 shows a circular substrate wafer 10, such as a silicon wafer used in the manufacturing industry. Such substrate wafers 10 having diameters of 200 mm or 300 mm are known in the art. The thickness of typical silicon wafers 10 lies between 600 and 800 μm. Apart from silicon, such substrate wafers 10 can be made from germanium, InP or GaAs, as examples. A first embodiment of the invention is described as an example below in the context of a silicon substrate wafer 10 that also extends to different materials, especially the ones named above.

To prevent the propagation of mechanical cracks in the substrate wafer 10, crack stop structures 1 are positioned around the rectangular devices 2, i.e., chips in this particular case on the substrate wafer 10. In the context of this description, a device is a piece cut from the substrate wafer 10 in the process of manufacturing a semiconductor device. The device can be, e.g., a processor chip or a memory chip such as a DRAM chip.

A single device 2 is depicted in the enlargement to the right in FIG. 1. The crack stop structures 1 are positioned relatively close to the kerf of the device, e.g. chip. For example, the crack stop structures 1 may be positioned within 1 to 50 μm of the kerf.

The crack stop structure 1 can take the shape of a trench that has been etched as a depression into the substrate wafer 10. An example is shown in the cross section view of FIG. 1A. The depth d of the depression forming the crack stop structure 1 is preferably more than 5 μm, and can be 30 to 50 μm, as a more specific example.

If the substrate wafer 10 is used for DRAM manufacturing comprising deep-trench structures, the general rule for the depth d of the depression 1 would be at least as deep as the deep trenches in such a device. A typical deep trench has a depth of 6 μm. A possible range for the depth of deep trenches is 5 to 15 μm. The general rule for determining the depth d of the depression 1 (i.e., the deep trench) is that it should be at least 20% of the thickness of the substrate wafer 10 after backside grinding (see FIGS. 7A and 7B). Depths of less than 5% are also possible. Alternatively, the depression should be at least 10%, especially at least 5% of the thickness of the substrate wafer 10 after backside grinding.

Normally, backside grinding of a substrate wafer 10 is a common part of the semiconductor device manufacturing process. Backside grinding of a wafer 10 is depicted schematically in FIGS. 7A and 7B. The substrate wafer 10 is shown in a side view in FIG. 7A before the backgrind, in FIG. 7B after the backgrind. In FIG. 7B the final thickness of the substrate wafer 10 is reached.

The width w of the depression 1 in FIG. 1A is between 10 to 1000 nm.

The embodiment depicted in FIG. 1A shows a trench depression 1, which is not filled by another material. Another embodiment uses a trench of the same geometry as the depression 1 depicted in FIG. 1A but this depression 1 is filled, at least partially, with material that is typically used in a normal formation of the integrated circuit structures, as shown in FIG. 1B. Examples of such materials are tungsten, polycrystalline silicon and aluminum. Other examples are also possible.

The etching of the depression 1 can be performed by any known dry etching or wet etching process. Preferably an existing anisotropic dry etching process is used. One example is the deep trench etching process in trench DRAM manufacturing. This is especially economical if a deep etch process step (e.g., deep trenches, holes) is already performed on the substrate wafer 10 in the normal process flow.

Furthermore, deep etching steps are regularly necessary in the manufacturing of microelectromechanical systems (MEMS) or in the manufacturing of chips with complex 3D vias such as the through etches described in the article “Ultra-Low Resistance, Through-Wafer Via (TWV) Technology and Its Applications in Three dimensional Structures on Silicon” by Soh, et al. (Jpn. J. Appl. Phys. Vol 38, 1999, pp. 2393-2396), which article is incorporated herein by reference.

The depression 1 forms the crack stop structure deflecting cleave lines running through the bulk of the substrate wafer 10 and shunts them to the surface of the substrate wafer 10. Therefore, the depression prevents cleave lines from extending into the sensitive region of the substrate wafer 10, i.e., the active area 2 within the depression 1.

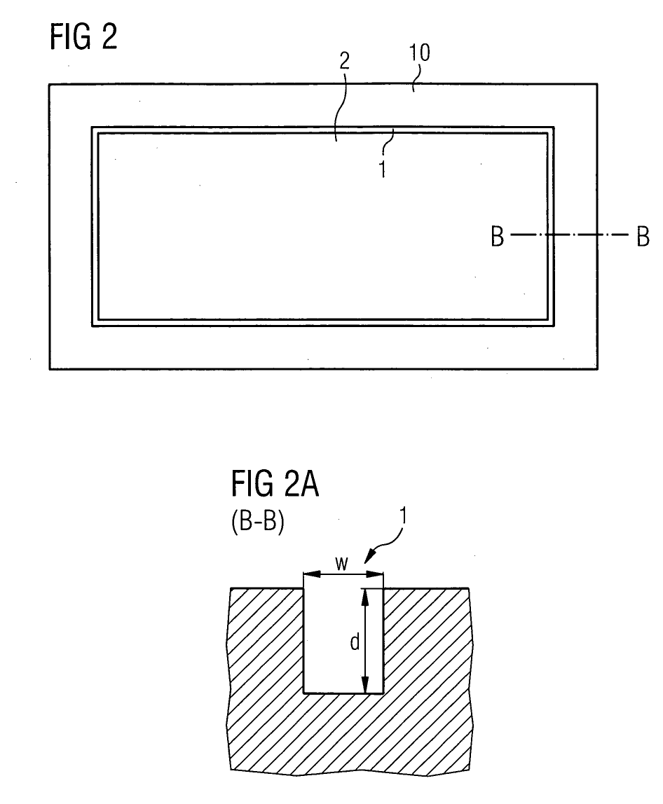

The embodiment depicted in FIGS. 2 and 2A shows basically the same structure as depicted in FIGS. 1 and 1A so that reference to the above description is made.

The embodiment shows a chip or device 10 with a rectangular shape. The depression 1, being a trench, is also shaped rectangular running parallel to the edges of the substrate wafer 10.

It should be noted that the scope of the patent includes more complex forms of continuous depressions 1, which can be combinations of curved depressions and linear depressions 1 (as in FIG. 2).

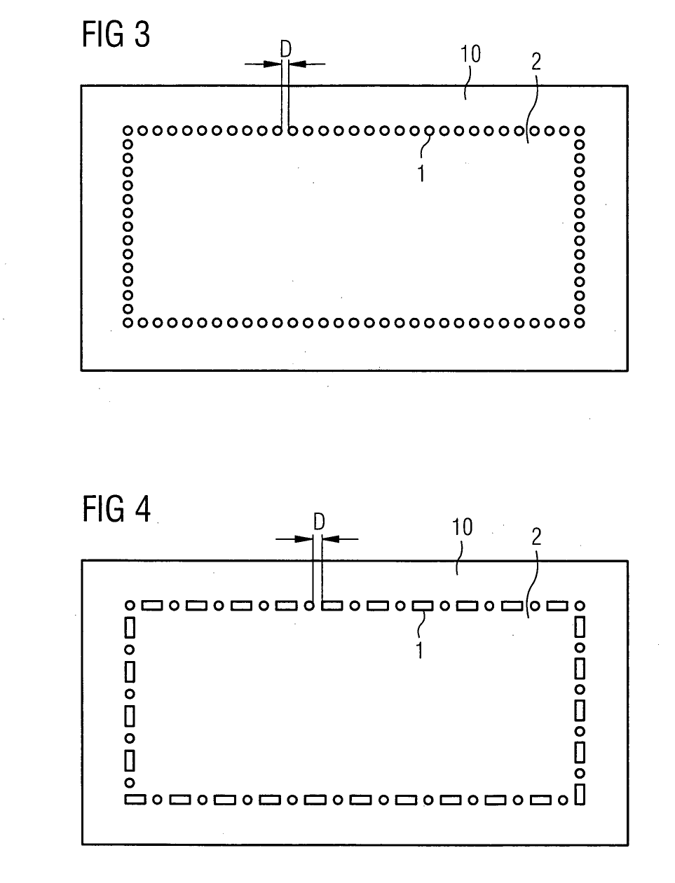

The second embodiment of the invention is depicted in FIG. 3. The basic structure of the embodiment is the same as in FIG. 2 since the chips or devices 10 are rectangular. But the crack stop structure 1 is not made of a continuous trench but a series of holes all lined up linearly. The distance D between the holes is preferably 1 to 10 times the diameter of the holes. The diameter of the holes can be as a minimum the same size as a deep trench structure and a maximum of ten times the size of a deep trench structure.

A person skilled in the art will also realize that a crack stop structure 1 on the chip or device 10 can be formed from combinations of continuous trenches and holes or depressions. Just one example of such a crack stop structure 1 is the embodiment depicted in FIG. 4.

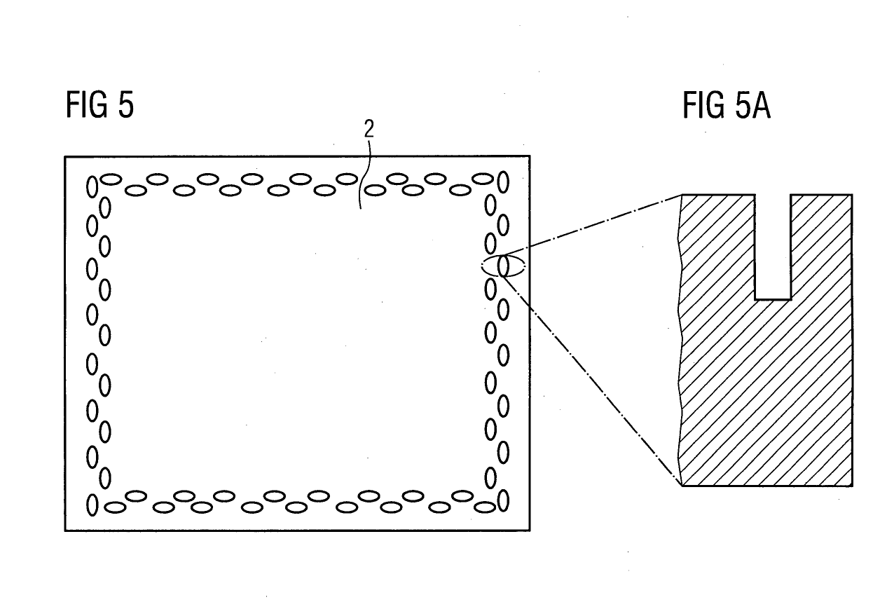

FIG. 5 shows another embodiment, in which the depression 1 is formed from a series of trenches. The trenches are positioned in a zig-zag like pattern. FIG. 5A shows a cross-section of one of the trenches.

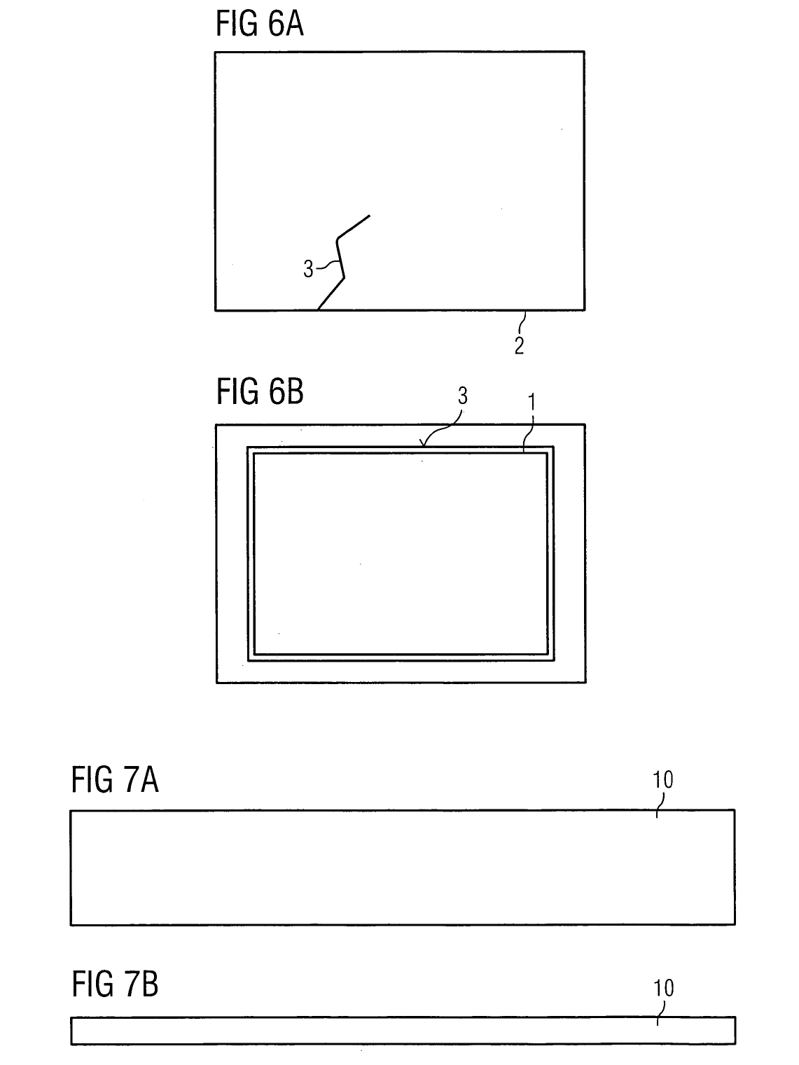

In FIGS. 6A and 6B the effect of the depression for stropping cracks is shown. Without a crack stop the fissure 3 can permeate into the device 2 or chip. With a depression 1 around the device 2 or chip the fissure 3 terminates at the depression 1.

In FIGS. 7A and 7B the silicon substrate wafer 10 is shown in a side view. FIG. 7A shows the silicon substrate wafer 10 before the backgrinding, FIG. 7B after backgrinding.

Even though the embodiments of the invention are described in connection with a silicon substrate wafer 10, the person skilled in the art will notice that the same or similar crack stop structures 1 could be applied to other semiconductor substrate wafer materials such as GaAs or germanium. GaAs wafers have thickness between 400 and 500 mm so that the dimensions of the depression 1 would have to be adjusted accordingly.

A typical application of a crack stop structure 1 as described would be in a substrate wafer 10 used in the production of microelectromechanical systems (MEMS) or in devices comprising complex three dimensional structures.

The crack stop structure 1 can be produced, e.g., by an etching process such as etching a deep contact, a wet etch process, a dry etch process or a through etch.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A structure for stopping mechanical cracks in a substrate wafer used for semiconductor device manufacturing, wherein the structure comprises at least one depression extending into the substrate wafer for at least 5% of the final thickness of the substrate.

2. The structure according to claim 1, wherein the substrate wafer comprises a silicon wafer.

3. The structure according to claim 1, wherein the at least one depression extends into the substrate wafer for at least 20% of the final thickness of the substrate.

4. The structure according to claim 1, wherein the at least one depression is shaped at least partially as a trench in the substrate wafer.

5. The structure according to claim 1, wherein the at least one depression is shaped at least partially as a hole in the substrate wafer.

6. The structure according to claim 1, wherein the at least one depression is at least part of one of the group of a contact etch and a-through etch.

7. The structure according to claim 1, wherein the at least one depression extends more than 5 μm into the substrate wafer.

8. The structure according to claim 1, wherein the at least one depression is positioned within about 1 to 50 μm of a kerf of the device.

9. The structure according to claim 1, wherein the at least one depression is part of a deep trench structure having depth between 5 to 15 μm.

10. The structure according to claim 1, wherein the at least one depression has, at least partially, a width between 10 to 1000 nm.

11. The structure according to claim 1, wherein the at least one depression has, at least partially, a diameter between 10 to 1000 nm.

12. The structure according to claim 1, wherein the at least one depression has a depth of one to ten times a deep trench depth.

13. The structure according to claim 1, wherein the at least one depression has a width of one deep trench size.

14. The structure according to claim 1, wherein the at least one depression has a diameter of one deep trench size.

15. The structure according to claim 1, wherein a diameter of the at least one depression is smaller than a diameter of a through silicon contact etch.

16. The structure according to claim 1, wherein the at least one depression is one of the group of holes and trenches.

17. The structure according to claim 1, wherein the at least one depression comprises at least three depressions that are positioned linearly adjacent to each other.

18. The structure according to claim 1, wherein the at least one depression comprises a plurality of depressions that are located in a zig-zag arrangement.

19. The structure according to claim 1, wherein the at least one depression comprises sets of at least two depressions positioned in a continuous sequence that has a crush that distance between the depressions.

20. The structure according to claim 19, wherein the distance between the two depressions is one to ten times a diameter of one of the depressions.

21. The structure according to claim 1, wherein the at least one depression is at least partially etched into the substrate wafer.

22. The structure according to claim 1, wherein the at least one depression is filled with a material.

23. The structure according to claim 1, wherein the substrate wafer further includes a microelectromechanical system (MEMS).

24. The structure according to claim 1, wherein the substrate wafer includes a plurality of 3D chips.

25. A method for manufacturing a semiconductor device, the method comprising:
providing a semiconductor wafer;
forming a plurality of active structures in die areas of the semiconductor wafer; and
forming structures for stopping mechanical cracks in the semiconductor wafer, the structures surrounding each of the die areas, wherein each structure comprises at least a depression extending into the semiconductor wafer to a depth of at least 20% of a final thickness of the semiconductor wafer.

26. The method according to claim 25, further comprising etching the depressions into the semiconductor wafer.

27. The method according to claim 26, wherein etching the depressions comprises performing at least one process selected from the group consisting of etching a deep contact, a wet etch process, a dry etch process and a through etch.

28. The method according to claim 26, wherein the etch is performed anisotropically.

29. The method according to claim 25, further comprising dicing the semiconductor wafer using a micromachining process, wherein each of the die areas is diced into a separate device.
